(19) United States
(12) Patent Application Publication
(10) Pub. No.: US 2024/0022019 A1
(43) Pub. Date: Jan. 18, 2024

(54) USB Gripping Connectors

(71) Applicant: Xiaozheng Lu, Dallas, TX (US)

(72) Inventor: Xiaozheng Lu, Dallas, TX (US)

(21) Appl. No.: 18/217,882

(22) Filed: Jul. 3, 2023

Related U.S. Application Data
(60) Provisional application No. 63/389,643, filed on Jul. 15, 2022.

(51) Int. Cl. H01R 13/62

(52) U.S. Cl. CPC H01R 13/62; H01R 13/7175

(57) ABSTRACT

Provided are embodiments for Universal Serial Bus (USB) male gripping connectors for USB A, USB B, and USB-C connectors. Each embodiment provides 3 to 4 times the pull-out force to keep the connectors mated to the female connector. Each embodiment is backwards compatible with existing female connectors. Embodiments connectors also include partition walls on the connector plug body's inner PCB to divide the PCB into high frequency and low frequency sections or chambers, thus allowing LED lights to protrude out for visualization while maintaining a superb near airtight EMI shielding in the high frequency section or chamber of the connector.

This application claims priority to U.S. Provisional Application No. 63/389,643, filed Jul. 15, 2022.

### FIELD OF THE INVENTION

The invention relates to new technologies and designs in Universal Serial Bus (USB) male connectors that greatly increase the forces needed to pull the connectors out to make more secure connector mating and prevent the unintentional signal loss due to insecure connector mating yet do not permanently lock onto the female connectors to prevent unintentional sudden pulls that can break the devices with the female connectors to create bigger problems and losses. Crucially, embodiments male connectors are still fully backwards compatible with all the existing female connectors already in use commercially. The new male connectors have the identical dimensions as the existing male connectors thus can fit into even the tightest space of any products the mating female connectors are on. These male connectors facilitate applications for mobile, professional, and home use of USB based signaling. Preferred embodiments use one or more thin metal pieces to stand up on the Printed Circuit Board (PCB) like walls to divide the PCB into several sections, thus allowing the low frequent signal section to have open holes on the connector plug body metal can so the lights can come out for indications. This segmenting of the PCB maintains the other high frequency signal section that can have airtight metal containment or wrapping for Electromagnetic Interference (EMI) shielding.

### BRIEF DESCRIPTION OF THE DRAWINGS

FIG. 1 schematically shows a prior art male USB-G connector with a top locking screw.

FIG. 2 schematically shows a prior art male USB-C connector with two side locking screws.

FIG. 3 schematically shows one embodiment of the current invention USB A male “X-grip” connector in 3D component view.

FIG. 4 schematically shows one embodiment of the current invention USB A male “X-grip” connector in 2D component views in 3 angles.

FIG. 5 schematically shows one embodiment of the current invention USB A male “X-grip” connector in 3D front-bottom view.

FIG. 6 schematically shows one embodiment of the current invention USB A male “X-grip” connector in 3D rear-top view.

FIG. 7 schematically shows one embodiment of the current invention USB A male “H-grip” connector in 3D rear-top view.

FIG. 8 schematically shows one embodiment of the current invention USB A male “Y-grip” connector in 3D rear-top view.

FIG. 9 schematically shows one embodiment of the current invention USB B male “X-grip” connector in 3D component view.

FIG. 10 schematically shows one embodiment of the current invention USB B male “X-grip” connector in 2D component views in 3 angles.

FIG. 11 schematically shows one embodiment of the current invention USB B male “X-grip” connector in 3D front-bottom view.

FIG. 12 schematically shows one embodiment of the current invention USB B male “X-grip” connector in 3D rear-top view.

FIG. 13 schematically shows one embodiment of the current invention USB B male “H-grip” connector in 3D rear-top view.

FIG. 14 schematically shows one embodiment of the current invention USB B male “Y-grip” connector in 3D rear-top view.

FIG. 15 schematically shows one embodiment of the current invention USB-C male “H-grip” connector in 3D component view.

FIG. 16 schematically shows one embodiment of the current invention USB-C male “H-grip” connector's internal “H-grip” gripping hook or latch.

FIG. 17 schematically shows a prior art connector plug inner Printed Circuit Board (PCB) with several Light Emitting Diodes (LEDs) for indications. The metal container or can has open holes to allow the lights from the LEDs to protrude out for visualization.

FIG. 18 schematically shows one embodiment of the current invention connector plug inner PCB that has one or several thin metal walls on the PCB to divide the PCB into several sections based on the signal frequency. Thus, the PCB is able to maintain the air tight JR Nshieling for blocking high frequency signals.

### BACKGROUND

Universal Serial Bus or USB (referred as “USB” in this application) is an industry standard that establishes specifications for cables, connectors and protocols for connection, communication, and power supply (interfacing) between computers, peripherals, and other computers. It was first released in 1996 and now there are estimated 10 billion devices in use with USB ports, making it one of the most successful technology standards ever. Further, the European Union has mandated devices use USB-C by the year 2026 establishing USB's longevity into the future.

USB was initially designed for connecting devices with short cables of a few meters long. There are no secure locking or gripping mechanism to provide force to prevent detachment designed in USB Type A (short for “USB A”) or USB Type B (short for “USB B”) connectors at all, and almost no one uses the locking USB Type C (short for “USB-C”) cables for reasons discussed in the next paragraph. As a result, the USB connections are not considered secure for attachment and can easily detach from connected devices. There is always the chance for the connector to come loose or detached causing troublesome problems that are easily fixed but require time, labor and embarrassment that a detached USB cable was the cause of connectivity problems. For example, when the connector is detached, and the signal gets lost during use especially the critical business live presentation. This problem becomes worse when long cables are used due to the heavier cable weight from the thick wires and the active circuits in the connector plug body needed to go long distances. Also, the long-distance USB cables are often used by businesses in settings such as conference and board rooms where reliability is critical.

Many attempts have been made by different parties trying to resolve this insecure, detached, or loose connection issue, including the USB founder, the USB Promoter Group. This founders group introduced one type of locking connector specifications only for the USB-C. However, the locking USB-C connectors are not widely used due to its excessive connector plug body size that won't fit many tight spaces in device panels, lack of matching female connectors in use on the devices, and the potential of expensive device damages caused by the connected and locked USB-C cables being yanked or kicked unintentionally. This shows a need for gripping connectors for USB to solve problems of detaching in the field for this expanding technology.

### SUMMARY

The current invention provides multiple embodiment designs for each of the USB A, USB B and USB-C type connectors; the added components are only needed on the male connector side, and there is no need for any changes on the female receptacle connector side. This makes the USB gripping male connectors fully backwards compatible. Embodiments of the current invention USB gripping connectors increase the pull-out forces to 3 or 4 times of the existing non-gripping connectors, or about 30 to 40 N, but does not lock with the potential for unintentional and severe damage or difficulty removing the cable from devices. This is a carefully chosen pull-out or gripping force multiplier balancing the mating security need and the prevention of potential damage from unintentional pull out force. The connections won't be as secure if the pull-out forces are lower than this preferred force. The devices with female connectors can be damaged and cause significant interruption to usage and costs a lot to replace the broken devices if the pull-out forces are significantly higher than this force. Embodiments of the current invention create a range of solutions that are very secure, easy to implement, have no learning curves for users, are fully backwards compatible, and won't cause damages to expensive devices in user detachment accidents.

The prior art connector plug body often has a Printed Circuit Board (PCB) inside with electronics components. To shield the Electromagnetic Interference (EMI) to prevent the internal signals from emitting out of the cable and cause interference to other devices, and to prevent the external signals from getting into the cable component and causing interference to its connected devices. Most connector inner PCB or components are shielded with near airtight metal containers, cans, or copper tape wraps. For the connector plug body with LED indicators, the metal container or can or copper tape wrap must have open holes to allow the LED lights to protrude out for visualization. These open holes allow the EMI to come out or to get in, and often make the cables to be non-compliant with industry standards. Embodiments of the current invention provides a solution by adding partitions, for example by adding thin metal wall or walls of other suitable shielding material between the high frequency circuit and the low frequency circuits thus divided them into several “chambers”, so the open holes on the metal can or copper tape wrap in the low frequency circuit chamber would not affect the still near airtight high frequency chamber, and still maintain the superb EMI shielding in the high frequency chamber. Materials suitable for partitions include but are not limited to metals, metal alloys, plastics with conductive coating, conductive ceramics, hybrids of metal and ceramic or plastic materials provided they fulfill the EMI shielding required.

Embodiments include USB A or USB B gripping male connectors comprising an outside shell with a male plug for contacting a female receptacle via its outside shell; one or more raised crown on at least one surface of the connector's outside shell, where the raised crown is protrudes-out from the metal and is raised above the at least one surface of outside shell; the one or more raised crown further comprising one or more ramps separated from the surface of the connector's outside shell by at least one slot, one or more dome of the raised crown; where the one or more slot and one or more ramp form a base of the dome of the raised crown, and the one or more slot and one or more ramps, provides flexibility or give to allow the one or more raised crown to move downwards when the top of the raised crown or cone is compressed by the inner surface of the female receptacle's outside shell when the male plug is inserted into the female receptacle to create greater gripping force by friction. Embodiments include USB A or USB B male gripping connector where the raised crown further comprises four slots, four ramps, and one dome, where the ramps and slots form an X like configuration around the dome of the raised crown. Other embodiments include male gripping connector where the raised crown has two slots, two ramps, and one dome, where the ramps and slots form an H like configuration around the dome of the raised crown. Still other embodiments include USB A or USB B male gripping connectors where the raised crown has three slots, three ramps, and one dome, where the ramps and slots form a Y like configuration around the dome of the raised crown. Additional embodiments include USB A or USB B male gripping connectors where the raised crown further comprises a plurality of ramps and slots and wherein the ramps and slots forms a V, T, C, or K like configuration around the dome of the raised crown. Different embodiments include USB-C male gripping connector comprising one or more member comprising one or more finger positioned in the inner portion of the male plug; where the one or more front fingers further comprises one or more tips where each of the tips is a trapezoid hook, where the junction between each side of the trapezoid hook is rounded; where the one or more tips is configured to slide through the inner surface of a mating female connector when inserted and drops into the one or more notch in the inner surface of the female connector to provide the increase gripping force when the male connector is fully inserted. Embodiments include male USB-C gripping connectors where the member further comprises a left and a right member and a cross member perpendicular between the left and right member forming a H like configuration, where each of the left and right member comprises a tip. Other embodiments include USB-C gripping male connectors where the tip's hook is configured with an entry angle of about 30 to about 36 degrees; and where the tip's hook is configured with an exit angle of about 60 to about 80 degrees. Still other embodiments include male USB-C gripping connector of claim where the width of a front portion of the left and right member's tip is from about 1.6 to about 1.9 mm; where the width of the middle portion of the left and right member is from about 3 to about 4 mm; where the width of the rear portion of the left and right member is from about 3.6 to about 5.0 mm, and where the members are about 0.2 to about 0.4 mm in thickness. Further embodiments include USB Male gripping connectors where the gripping force is about 20 N to about 50 N. Some embodiments include male gripping connectors, where the members are about 0.2 to about 0.4 mm in height. Other embodiments include male gripping connectors where the members are not for electrical grounding connection purposes.

Embodiments of this invention are at least one raised crown on the USB A or USB B male connector's outside metal shell. The crown can be punched outwards into one of the several shapes on at least one outer surfaces on the outside metal shell. These raised crowns have a dome and behave like non-locking springs that grip via friction. Once the male USB A or USB B male connector is inserted into a matching USB female receptacle connector, these raised crowns and dome on the outer surface of the male connector's outside shell are compressed by the inner surface of the female connector's outside shell and generate outwards pressure. The pressure creates friction between the male and female connectors, and increases the grip or the force needed to pull out the male connector from the female connector. With different embodiments of the overall raised crowns dome height, width, gap length and width between the raised crown's dome or peak and the metal shell base surface, metal material thickness and hardness, the gripping or pull-out force can be designed to different forces for the needs of the application or type of USB connector (i.e., Type A, Type B). The ideal pull-out force should be designed to be about 3 to 4 times of the pull-out force of the regular non-gripping connectors or about 30 to 40 N (Newton). This force is strong enough to secure the USB Type A or B Male connector probe, but does not risk locking or require a force that can damage devices such as would be present for locking connectors.

The physics that makes the gripping raised crowns work in the last paragraph is simple: pressure creates friction, but must meet requirements of USB design and specifications for size and compatibility to female connectors for back ward compatibility. Although, shown are the X shaped raised crowns dome (X-grip) overall configuration, H shaped raised crowns dome (H-grip) overall configuration and Y shaped raised crown dome (Y-grip) overall configuration for embodiments in this application, other shapes and overall configurations are contemplated for the raised crowns that serve as added embodiments and provide the same physics function of using pressure to create friction to increase the pull-out force of the connector. Such further embodiments include but not limited to V, T, C, K shapes among others that would be known to a skilled engineer as feasible to generate the requisite force. Each overall configuration utilized the raised crown and dome in combination with one or more slots to allow the raised crown in its overall configuration to move up and down to provide for gripping at a desired force in compliance with USB A or B dimensional and force requirements for the pull-out force (e.g., X, H, Y, V, T, C, or K configuration).

The USB-C connectors need a different mechanism to increase the gripping force, because the USB-C male connector's outside shell is made of much thicker metal and is rigid, which does not allow any punched-out raised crowns with slots to serve the spring like movement for gripping force. Embodiments of this invention on the USB-C male connectors are a H like three-member element comprising a left, right fingers, with tips ending in trapezoidal hooks and a cross member. Such H like members are inside the male probe of the connector and provide the hooking or latching function between the left and right finger's tips or trapezoidal hooks at the two front ends of the H like element on the male connector and the two matching left and right hooks inside the female connector. This design increases the grip or the force needed to pull out the male connector from the female connector. With different embodiments of the H like hooks' entry angle (from about 30 degrees to about 36 degrees) and exit angle (from about 60 to about 80 degrees), the H like member arm's width, thickness and material hardness, the gripping or pull-out force can be designed to different numbers. The ideal pull-out force should be designed to be about 3 to 4 times of the pull-out force of the regular non-gripping connectors. In many embodiments this is about 30 N to about 40 N. Crucially, embodiments of the current invention do not lock in place, and rather use friction or other means thereby ensuring detachment without damaging connected devices.

The physics that makes the left and right fingers with hooks work in the last paragraph is simple: creates friction, but must meet requirements of USB-C design and specifications for size and compatibility to female connectors for backward compatibility. Although, embodiments of the current invention show the H like element in this application with two hooks at the left and right ends of the H like element, any other shaped element, of any other width, thickness of the shaped element, or any other number of hooks, or any other hook entry and exit angles, among other variations that would be known to a skilled engineer that serve the same physics hook function to increase the connector's pull-out represent additional embodiments of this invention.

Embodiments include a connector plug body comprising a Printed Circuit Board (PCB) with one or more Light-Emitting Diodes (LED), PCB traces, an Electromagnetic Interference (EMI) shieling container, wherein the EMI shielding container can be chosen from the group consisting of a metal can, a copper tape wrap, and conductive ceramic; where the shielding container further comprises one or more openings matching the positions of the LEDs on the PCB to allow the LEDs to protrude so that light can be visualized from the LEDs, where at least one partition wall configured on the PCB connected to the ground circuit and where the at least one partition places all the high frequency components and PCB traces in one section of the PCB, and all of the low frequency components including the LEDs and PCB traces in another section of the PCB; and where the top of the at least one partition wall is in secure contact of the inner side of a top surface of the EMI shielding container to form near airtight EMI shielding for the inner chamber in the high frequency section of the PCB. Additional embodiments include a connector plug body, where the connector can be USB, HDMI, DP, VGA, and other connector types. Still other embodiments include a connector plug body where the partitions walls are made of material chosen from the group consisting of copper, tin, aluminum, steel, other conductive metals, and conductive ceramic.

In the other preferred embodiments of the current invention the connector plug's inner PCB has partitions that allows the LED lights to come out of the connector body for indications yet still be shielded for chambers with the high frequency signals for EMI. The inner PCB inside the connector body is designed that all the high frequency signal components and traces are configured to be in one physical section of the PCB by partitions, while the low frequency, DC power and LED indication components and traces are in another physical section or chamber of the PCB. These high frequency section and low frequency section are divided by the thin metal wall or walls or other suitable material placed in between these sections. These divider thin metal or other material walls are grounded in circuits, and form near airtight EMI shielding in the high frequency section together with the overall metal container, can, or copper tape wrap, while still allowing for the open holes on the overall metal container or can or copper tape wrap for the LED lights to protrude out for indication. Such embodiments partitions and chambers do not affect the EMI shielding in the high frequency section due to isolation by the added thin metal wall or other material walls in between.

### DETAILED DESCRIPTION

### Prior Art USB-C Screw Locking Connectors

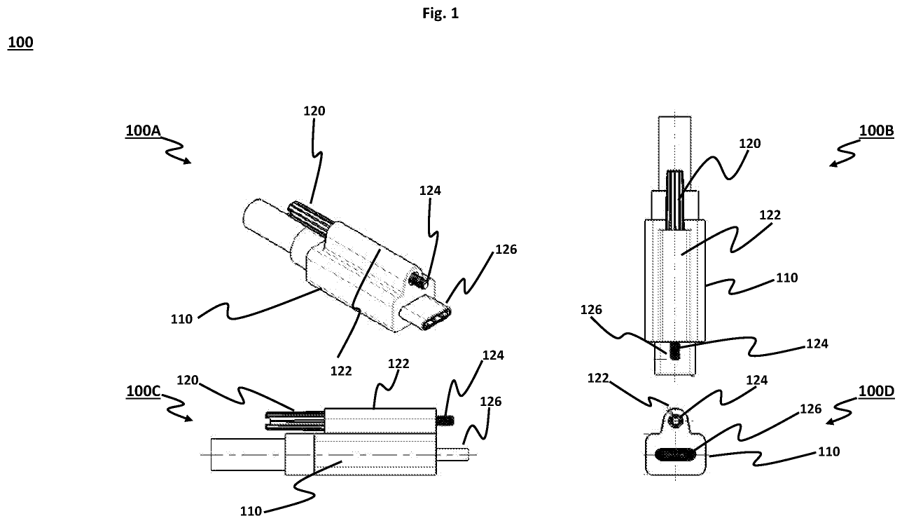

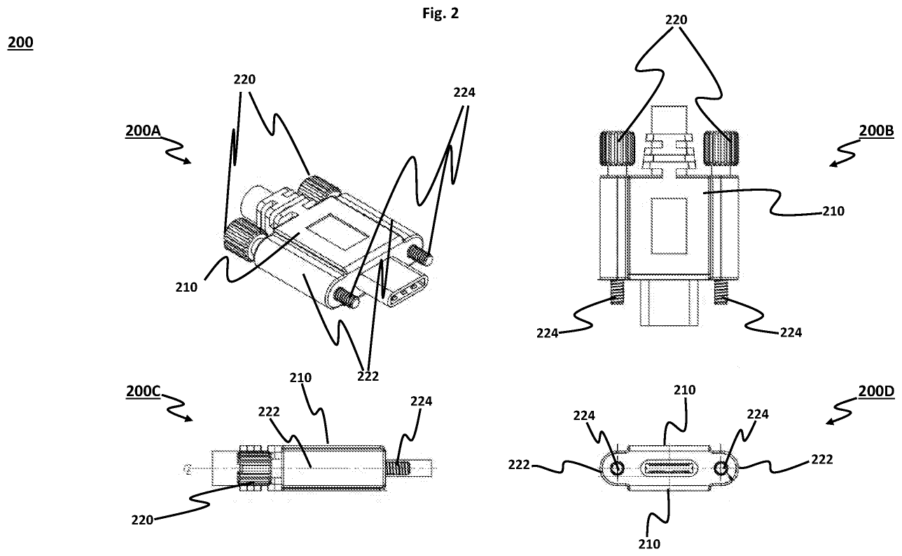

Referring to FIG. 1, view 100, shown schematically are four views (100A, 100B, 100C, and 100D) of a prior art USB-C male connector with one top locking screw 124. A screw shaft 122 is added on top of the USB-C connector body 110, which allows a long locking screw with screw threads 124 in the front for screwing into the matching screw hole on the female USB-C connector, with the thumbnail 120 positioned in the rear for the user's fingers to grab and turn the screw. The screw shaft 122 adds extra space on top of the regular USB-C male connector body 110; the matching screw hole on the female connector side adds extra space on top of the regular USB-C female connector. A male probe 126 projects to mate with the female receptacle. Often, modern electronics devices like the smart phones are very thin and may not have such extra space on top of the connector for use of this type of USB locking connector. So, this type of the locking connector may not fit most of the devices. One alternative is to use the USB-C male connector with two side locking screws as shown in FIG. 2 and described in the next paragraph.

Referring to FIG. 2, view 200, shown schematically are four views (200A, 200B, 200C, and 200D) of a prior art USB-C male connector with two side locking screws 224. Two screw shafts 222, one on the left side, one on the right side are added to the regular USB-C male connector body 210, which allows two long locking screws with screw threads 224 in the front for screwing into the matching screw holes on the female USB-C connector, and the thumbnails 220 in the rear for the user's fingers to grab and turn the screws. The screw shafts 222 adds extra space on the two sides of the regular USB-C male connector body 210; the matching screw holes on the female connector side adds extra space on the two sides of the regular USB-C female connector. Often, modern electronics devices, like the smart phone, are very small and may not have such extra space for the two sides of the connector. So, this type of locking connector may not fit most of the modern devices.

In addition to the hard-to-find extra spaces needed to fit any of these two prior art USB-C locking connectors, such locking USB-C male connectors are also not backwards compatible, meaning they cannot be used with billions of devices already in the market that do not have the matching locking screw holes on the female side. Even more problematic, once the screws are turned in and fully locked, if the users move the portable devices like the smartphones or laptop computers without realizing the USB-C cables are locked in place, they can break the female connectors off the main circuit board and cause the major disruptions to the business meeting they are doing the presentations. This type of damage is very expensive to repair or may require replacement and add overall costs for a company's annual use of smart phones or laptop computers from damage and loss. These are the reasons the USB-C locking connectors are hardly in use by laypeople or professionals in the variety of places where USB connector are used and also why the whole industry is still searching for a reliable, low cost, permanent damage free solution for secure USB connector mating. That's what this patent application brings in its various embodiments to address this large unmet need. See the detailed descriptions in the following paragraphs.

### Embodiments of the Current Invention: USB A Gripping Connector; the Positioning of the “Raised Crowns”

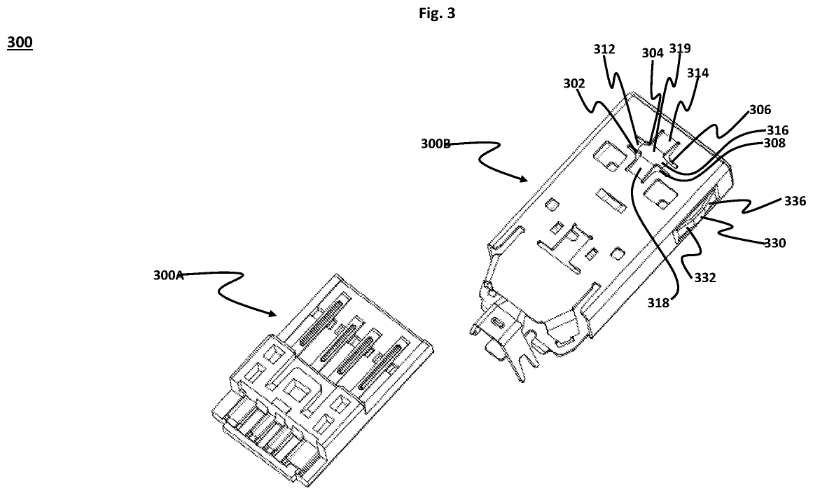

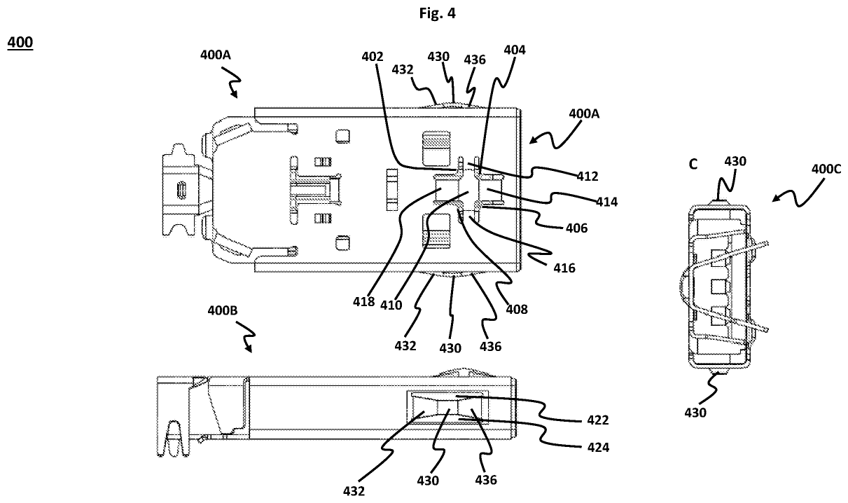

Referring to FIG. 3, 300, a 3D view from the top/right-side/rear angle of a USB A male connector, shown schematically is one embodiment of the current invention adding the punched out “raised crowns” on the USB A male connector's outside shell to increase the gripping force required to pull out this male connector from the mating female connector by increased friction by these “raised crowns”. In this example, 300A is the traditional USB A male connector's “connector core” with contact pins for electrical connections; and the 300B is the outside metal shell to form the connector's mechanical frame in the front of the connector for mating with female connector, to form the mechanical frame in the rear of the connector that crimps onto the bulk wire to the front of the connector; and to provide electrical shielding for all the inner signal pins from the outside EMI (Electromagnetic Interferences). The current invention adds one or more punched out “raised crowns” that may have a top of the dome or peak 319 represented by the elements 302, 304, 306, and 308 for slots and 312, 314, 316 and 318 for ramps that together are configured on the top surface of the connector's outside shell. One or more punched out raised crowns represented by the elements 330, 332 and 336 on the right-side surface, and other punched out raised crowns on the left-side surface (2 slots are on either side of the rpms and dome are not shown in this view but are present; left side not visible from this view and not shown). The shape and functions of these elements will be discussed in further detail in the paragraphs describing FIGS. 4, 6, 7 and 8.

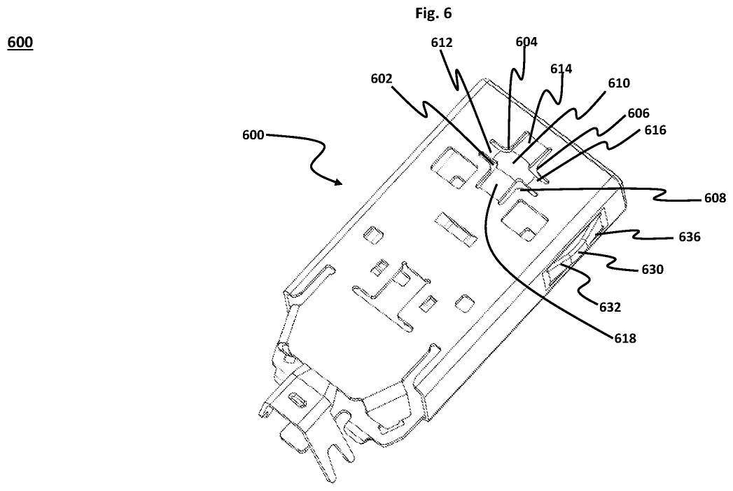

Referring to FIG. 4, 400, a top, right-side and rear 2D views of the same connector in FIG. 3, shown schematically is one embodiment of the current invention USB A male connector with punched out raised crowns and slots configured in an overall “X” shape on the outside shell. The raised crown dome elements on the top surface are comprised of four slots 402, 404, 406, and 408 with four ramps 412, 414, 416, 418 and 410 the top of the crown or dome are visible on the top view 2D drawing 400A and on the right-side view 2D drawing 400B. Embodiments include where the sides of the shell also have the raised crown dome elements 430, and ramps 432 and 436 on the left-side surface and the elements 430, and ramps 432 and 436 with slots 422 and 424 on the right-side surface are both visible on the top view 2D drawing 400A; and on rear view 2D drawing 400C. The embodiment show has an “X” overall configuration on the top of the connector (“X”-Grip). The shape and functions of these elements will be discussed in details in the paragraphs describing the FIGS. 6, 7 and 8.

### Embodiments of the Current Invention: USB A Gripping Connector; the Different Configurations of the “Raised Crowns” on the Side Surfaces of the Outside Shell

Still referring to FIG. 4, now on the section 400B, the right-side view of a USB A male connector's outside shell. This is one embodiment of the current invention's punched out raised crown and dome on the right-side surface comprising of gaps or slots 422 and 424; the bridges or the ramps 432 and 436, and the raised crown dome or top 430 where the 2 ramps meet. The slots allow the ramps to move freely up and down providing force and give or flexibility. The top dome's smooth shape and the lack of sharp corners allows it to slide against the inner surface of the female connector's outside shell when mated into a female connector without being caught to any small open windows or other dents on the inner surface of the female connector's outside shell, and also prevent it from leaving any scratch marks on the inner surface of the female connector's outside shell. The purpose of embodiments of the current invention are to add the raised crown's dome to both the left-side surface and the right-side surface is to allow the male connector mated securely with female connector with gripping force and prevents the connector from moving or wobbling slightly in the left or right direction. This is only one embodiment of the current invention. Any other combinations of the positioning of the raised crowns, the number of the raised crowns, the shape of the raised crowns and domes or tops on the side surfaces of the USB A male connector's outside shell are all covered by additional embodiments of this invention as long as the raised crown and dome serve the purpose of increasing the gripping force when the male USB A connector is pulled out from the female USB A connector. For example, “V”, “T”, “C” and “K” overall configurations of ramps and slots represent additional embodiments of the current invention.

### Embodiments of the Current Invention: USB A Gripping Connector; why No “Raised Crowns” are Positioned on the Bottom Surface of the Outside Shell

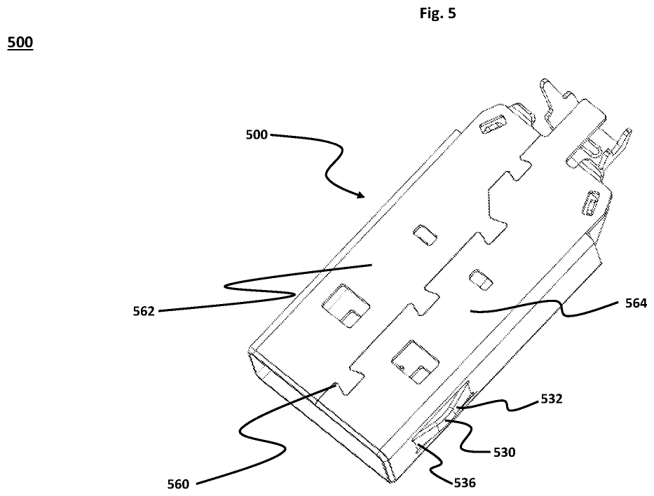

Referring to FIG. 5, 500, an 3D view is shown from the bottom/front/left-side angle of a USB A male connector with punched out raised crowns with slots on the outside shell. Here, the raised crown elements on the left-side surface dome 530, and ramps 532, and 536 are visible while the raised crown's dome 530 on the top surface and right-side surface are not visible from this angle. Normally the USB A male connector outside shell is made from a flat piece of thin metal and folded multiple times into the 3D metal shell shape shown in FIG. 5, with the seam 560 placed along the center line of the bottom surface between the left half 562 and right half 564 of the outside shell. If any punched out raised crowns are placed on this bottom surface either on the left half 562 or right half 564, when the raised crown's dome is compressed inwards when the male connector is mated with a female connector, the inward force would normally deform the half of the bottom surface of the outside shell where the raised crowns are located first. This would push the half of the bottom shell inwards in the vertical direction and outwards in the horizontal direction to make the seam 560 between the left half 562 and right half 564 wider, before depressing the punched out raised crown's dome, because the bottom surface of the outside shell is much larger in area than the punched out raised crowns. More importantly one side of the bottom surface shell is not securely fixed in place, rather is a free moving edge of the seam. This would make any punched-out raised crown's dome ineffective if placed on the bottom surface of the connector outside shell. This is the reason why in this embodiment of the USB A male gripping connector design, the punched-out raised crowns are not placed on the bottom surface of the outside shell. However, the preferred embodiments of this invention is to use the punched-out raised crown's dome on the outside shell surfaces to increase the friction or gripping force to pull the male connector out of the female connector. Nonetheless variant embodiments that include placement the punched-out raised crowns and domes on the bottom surface of the outside shell are included in this invention as well.

### Embodiments of the Current Invention: USB A Gripping Connector; the Different Shapes of the “Raised Crowns” on the Top Surface of the Outside Shell

Referring to FIG. 6, shown schematically is a one example of the current invention USB A gripping connector 600 comprising one or more “X-grip” punched out raised crowns, on the top surface of the USB A male connector's outside shell. This example of the overall configuration of an “X-grip” raised crown's dome has 4 open gaps or slots 602, 604, 606 and 608; and 4 bridges or ramps 612, 614, 616 and 618; and 1 of the crown's dome or top 610 where all 4 ramps joint together. In some embodiments a side configured punched out crown 630, and ramps 632, and 636 may be present. The slots allow the ramps to move freely up and down. The dome's 610 smooth shape and the lack of sharp corners allows it to slide against the inner surface of the female connector's outside shell when mated into a female connector without being caught to any small open windows or other dents on the inner surface of the female connector's outside shell. It also prevents the dome from leaving any scratch marks on the inner surface of the female connector's outside shell. The purpose of the current invention to add the raised crowns to the top surface is to allow the male connector mated securely with female connector with gripping and free from able to wobbling slightly in the up or down direction. This is only one of many embodiments of the current invention. Any other combinations of the positioning of the raised crowns, the number of the raised crowns, the shape of the raised crowns on the side surfaces of the USB A male connector's outside shell are all embodiments covered by this invention since the raised crowns serve the purpose of increasing the gripping force when the male USB A connector is pulled out from the female USB A connector.

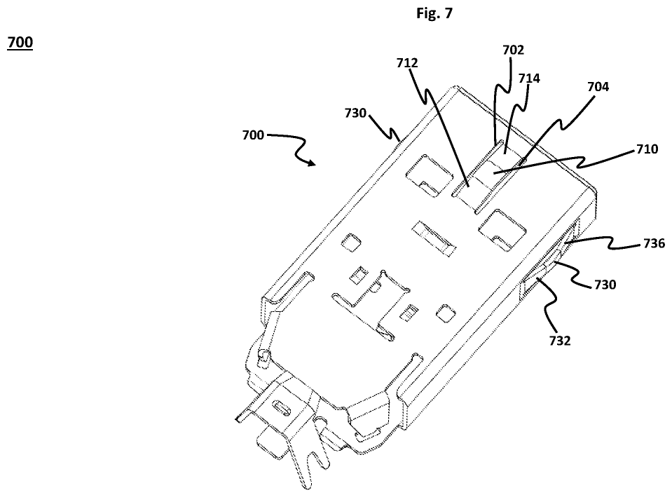

Referring to FIG. 7, shown schematically is a one example of the current invention USB A gripping connector 700 comprising one or more overall configuration “H-grip” punched out raised crowns, on the top surface of the USB A male connector's outside shell. The only difference of the components in FIG. 7 from FIG. 6 is that in FIG. 7, a different raised crown called “H-grip” replaced the “X-grip” in FIG. 6. This example of the “H-grip” raised crown has 2 open gaps or slots 702 and 704; and 2 bridges or ramps 712 and 714; and 1 top of the crown's dome 710, where all 2 ramps 712, 714 join together. Also shown is a right side punched out raised crown's dome 730 with 2 ramps 732, 736 (2 slots are on either side and are not shown in this view, but are present). Please see paragraph [0040] for further detailed description.

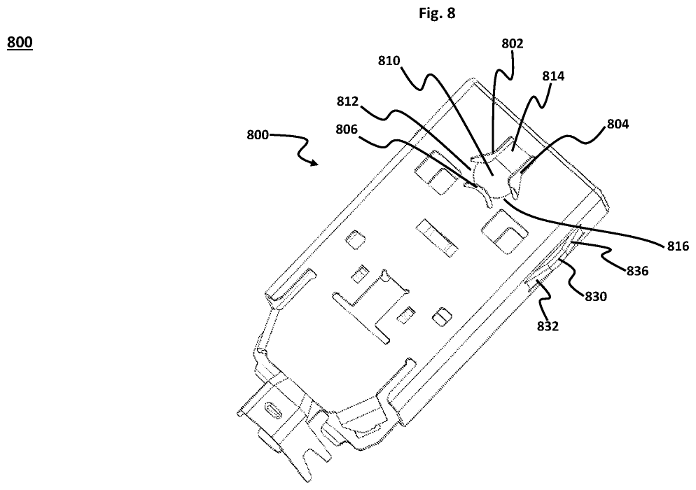

Referring to FIG. 8, shown schematically is a one embodiment of the current invention USB A gripping connector 800 comprising one or more “Y-grip” punched out raised crown's dome, on the top surface of the USB A male connector's outside shell. The only difference of the components in FIG. 8 from FIG. 6 is that in FIG. 8, a different raised crown called “Y-grip” replaced the “X-grip” in FIG. 6. This example of the “Y-grip” raised crown has 3 open gaps or slots 802, 804 and 806; and 3 bridges or ramps 812, 814 and 816; and 1 top or “dome” 810 where all 3 ramps joint together. Also shown is a right side punched out raised crown's dome 830 with 2 ramps 832, 836 (2 slots are on either side and are not shown in this view but are present). Please see paragraph [0040] for further detailed description.

### Embodiments of the Current Invention: USB B Gripping Connector; the Positioning of the “Raised Crowns”

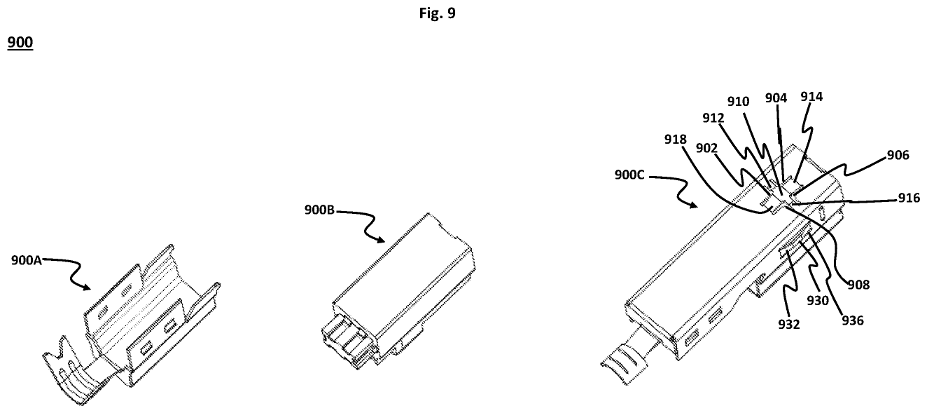

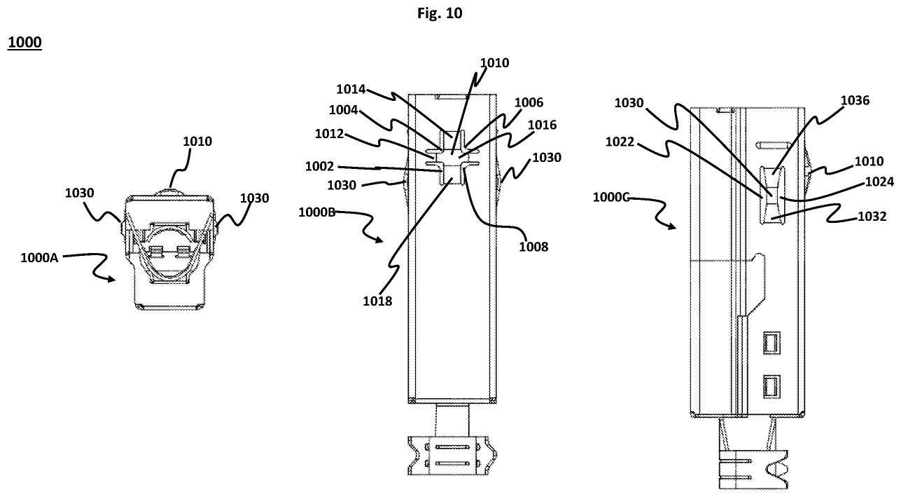

Referring to FIG. 9, 900, a 3D view from the top/right-side/rear angle of a USB B male connector, shown schematically is one embodiment of the current invention adding the punched out raised crowns, on the USB B male connector's outside shell to increase the gripping force to pull out this male connector from the mating female connector by increased friction by these overall differently configured shaped raised crowns (e.g., X, H, Y, V, T, C and K). In this example, 900A is the traditional USB B male connector's bottom metal shell; 900B is the traditional USB B male connector's “connector core” with contact pins for electrical connections; and the 900C is the top outside metal shell to form the connector's mechanical frame in the front of the connector for mating with female connector, to form the mechanical frame in the rear of the connector together with the lower metal shell 900A that crimps onto the bulk wire to the front of the connector; and together with the lower metal shell 900A to provide electrical shielding for all the inner signal pins from the outside EMI. Embodiments of the current invention add one or more punched out raised crowns with a dome or top 910, with 4 slots 902, 904, 906, and 908 slots and ramps 912, 914, 916 and 918 of the connector's outside shell top surface. One or more punched out raised crown's dome represented by the elements 932, 935 ramps and 930 dome top on the right-side surface (2 slots are not shown but are present. See FIG. 10, 1000C for the side slots, 1022 and 1024), and other punched out raised crowns and dome with slots and ramps may be on the left-side surface (not visible from this view). The shape and functions of these elements will be discussed in detail in the paragraphs describing FIGS. 10, 12, 13 and 14.

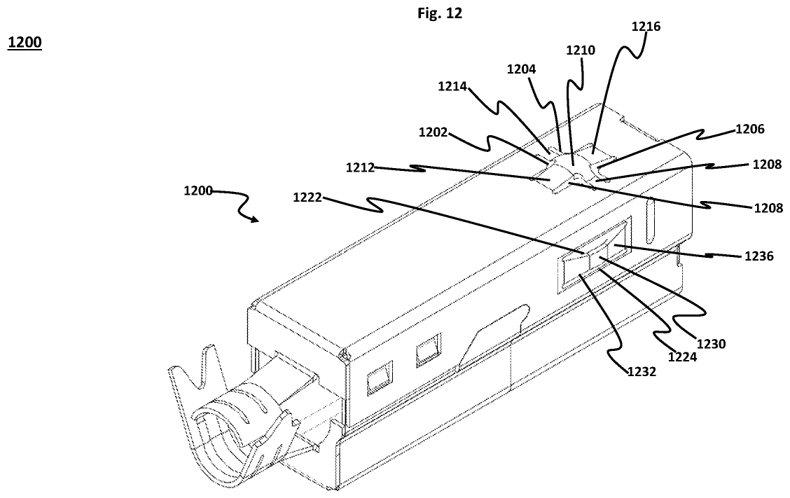

Referring to FIG. 10, 1000, a top, left-side and rear 2D views of the same connector in FIG. 9, shown schematically is a one example of the current invention USB B male connector with punched out raised crowns on the outside shell. The raised crown dome or top 1010 elements on the top surface and slots 1002, 1004, 1006, 1006 slots, and ramps 1012, 1014, 1016, and 1018 are visible on the rear view 2D drawing 1000A, on top view 2D drawing 1000B and on the left-side view 2D drawing 1000C. Here, the raised dome elements 1030 on the left-side surface and the elements 1030 on the right-side surface are both visible with slots 1022 and 1024, and ramps 1032 and 1036 on the top view 2D drawing 1000B; and on rear view 2D drawing 1000A (slots and ramps are not shown in 1000B top left and right punched out crowns. See 1000C below for such elements). The shape and functions of these elements will be discussed in detail in the paragraphs describing the FIGS. 10, 12. 13 and 14.

### Embodiment of the Current Invention: USB B Gripping Connector; the Different Shapes of the “Raised Crowns” on the Side Surfaces of the Outside Shell

Still referring to FIG. 10, now on the section 1000C, shown is the left-side view of a USB B male connector's outside shell. This is one example of the current invention's punched out raised crown dome or top on the left-side surface comprising of gaps or slots 1022 and 1024; the bridges or the ramps 1032 and 1036, and the top of the crown or dome 1030 where the 2 ramps meet. The slots allow the ramps to move freely up and down. The dome's smooth hemispherical or related shape and the lack of sharp corners allows it to slide against the inner surface of the female connector's outside shell when mated into a female connector without being caught to any small open windows or other dents on the inner surface of the female connector's outside shell, and also prevent it from leaving any scratch marks on the inner surface of the female connector's outside shell. The purpose of the current invention to add the raised crowns to both the left-side surface and the right-side surface is to allow the male connector mated securely with female connector with gripping and free from able to give or wobble slightly in the left or right direction. This is only one embodiment of the current invention. Any other combinations of the positioning of the raised crowns, domes, slots, and ramps, or the number of the raised crowns, domes, slots, and ramps or the shape of the raised crowns on the side surfaces of the USB B male connector's outside shell are additional embodiments of this invention since the raised crowns serve the purpose of increasing the gripping force when the male USB B connector is pulled out from the female USB B connector.

### Embodiments of the Current Invention: USB B Gripping Connector; why No “Raised Crowns” on the Bottom Surface of the Outside Shell

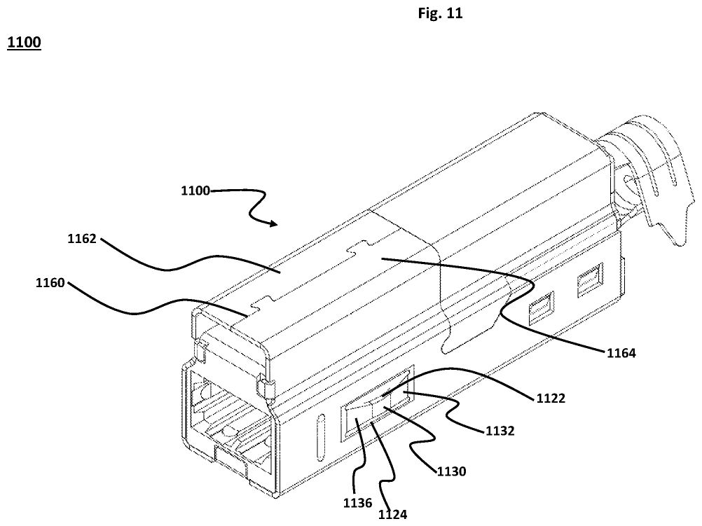

Referring to FIG. 11, 1100, a 3D view from the bottom/front/right-side angle of a USB B male connector with punched out raised crowns on the outside shell is shown. Here, the raised crown's dome slot elements on the left-side surface 1122 and 1124, ramps 1132 and 1136 and dome top 1130 are visible while the raised crown's dome on the top surface and right-side surface are not visible from this angle. Normally the USB B male connector outside shell is made from a flat piece of thin metal and folded multiple times into the 3D metal shell shape shown in FIG. 11, with the seam 1160 placed along the center line of the bottom surface between the left half 1162 and right half 1164 of the outside shell. If any punched out raised crowns with domes are placed on this bottom surfaces either on the left half 1162 or right half 1164, when the raised crown's dome are compressed inwards when the male connector is mated with a female connector, the inward force would normally deform the half of the bottom surface of the outside shell where the raised crown's domes are located first, to push the that half of the bottom shell inwards in the vertical direction and outwards in the horizontal direction to make the seam 1160 between the left half 1162 and right half 1164 wider, before depressing the punched out raised crown's dome. This is because the bottom surface of the outside shell is much larger in area than the punched out raised crown's dome, and more importantly one side of the bottom surface shell is not typically securely fixed in place due to industry manufacturing methods, rather is a free moving edge of the seam. This would make any punched-out raised crowns ineffective if placed on the bottom surface of the connector outside shell. This is the reason why in this embodiment of the USB B male gripping connector design, the punched-out raised crowns with domes are not placed on the bottom surface of the outside shell. However, the preferred embodiments of this invention use the punched-out raised crowns with domes on the outside shell surfaces to increase the frictions or gripping force to pull the male connector out of the female connector. Nonetheless variant embodiments that place the punched-out raised crown's dome on the bottom surface of the outside shell are included in this invention and could be manufactured by methods known by a skilled engineer such as molding or other technique.

### Embodiment of the Current Invention: USB B Gripping Connector; the Different Configurations of the “Raised Crowns” on the Top Surface of the Outside Shell

Referring to FIG. 12, shown schematically is a one example of the current invention USB B gripping connector 1200 comprising one or more of the overall configurations of the “X-grip” punched out raised crowns, domes, slots, and ramps on the top surface of the USB B male connector's outside shell. This example of the “X-grip” configured raised crown has 4 open gaps or slots 1202, 1204, 1206 and 1208; and 4 bridges or ramps 1212, 1214, 1216 and 1218; and 1 top of the crown's dome 1210 where all 4 ramps joint together. The slots allow the ramps to move freely up and down. The dome's smooth hemispherical or related shape and the lack of sharp corners allows it to slide against the inner surface of the female connector's outside shell when mated into a female connector without being caught to any small open windows or other dents on the inner surface of the female connector's outside shell, and also prevent it from leaving any scratch marks on the inner surface of the female connector's outside shell. The purpose of embodiments of the current invention are to add the raised crown's dome to the top surface is to allow the male connector mated securely with female connector with gripping and free from able to wobbling slightly in the up or down direction. This is only one example of the current invention. Any other combinations of the positioning of the raised crowns, the number of the raised crowns, the shape of the raised crowns on the side surfaces of the USB B male connector's outside shell are all embodiments covered by embodiments of this invention since the raised crown's dome serve the purpose of increasing the gripping force when the male USB B connector is pulled out from the female USB B connector.

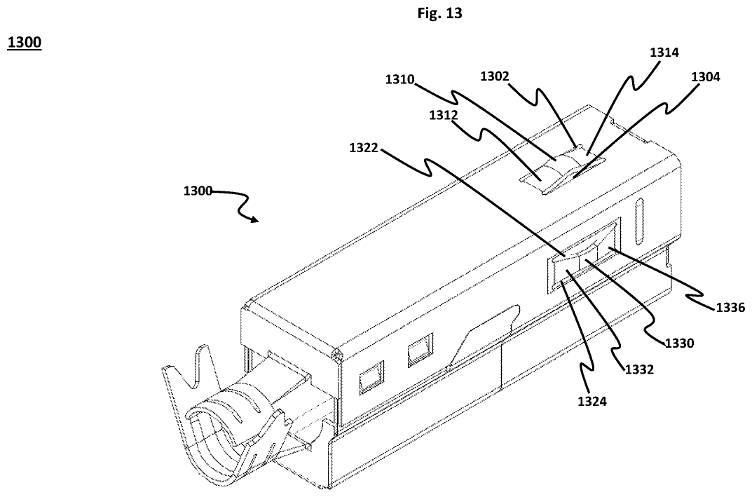

Referring to FIG. 13, shown schematically is a one example of the current invention USB B gripping connector 1300 comprising one or more of the overall configurations of the “H-grip” punched out raised crowns on the top surface of the USB B male connector's outside shell. The only difference of the components in FIG. 13 from FIG. 12 is that in FIG. 13, a different raised crown and dome are configured as an “H-grip” that replaced the “X-grip” in FIG. 12. This example of the “H-grip” raised crown's dome has 2 open gaps or “slots” 1302 and 1304; and 2 bridges or ramps 1312 and 1314; and 1 dome top of the crown 1310 where the 2 ramps joint together. Please see paragraph [0047] for further detailed descriptions.

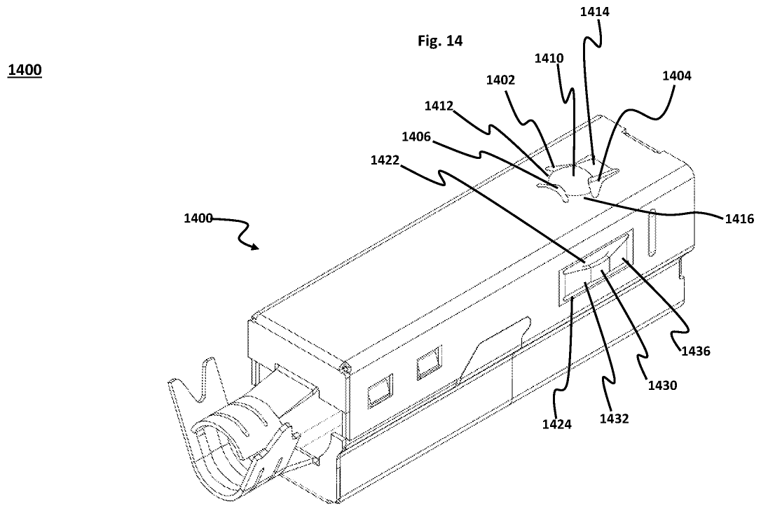

Referring to FIG. 14, shown schematically is a one example embodiment of the current invention USB B gripping connector 1400 comprising one or more of the overall configurations of the “Y-grip” punched out raised crowns on the top surface of the USB B male connector's outside shell. The only difference of the components in FIG. 14 from FIG. 12 is that in FIG. 14, a different raised crown's dome is configured as a “Y-grip” replaced the “X-grip” in FIG. 12. This example of the “Y-grip” raised crown has 3 open gaps or slots 1402, 1404 and 1406; and 3 bridges or ramps 1412, 1414 and 1416; and 1 dome top of the crown 1410 where all 3 ramps joint together. Please see paragraph [0047] for further detailed descriptions.

### Embodiments of the Current Invention: USB-C Gripping Connector

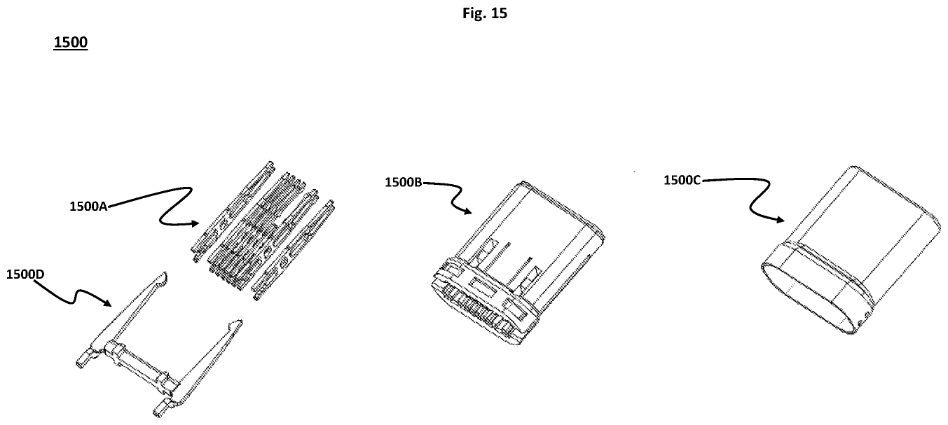

Referring to FIG. 15, a 3D view from the top/right-side/rear angle of a USB-C male connector's exploded component view, shown schematically is one embodiment of the current invention USB-C male gripping connector. Shown in 1500A are the internal pins of a USB-C connector; 1500B is the molded internal body of a USB-C connector; 1500C is the outside shell of a USB-C connector. Unlike the outside shell of a USB A connector (FIG. 5 item 500) or of a USB B connector (FIG. 11 item 1100) which is folded from a thin piece of metal sheet and has a gap or seem at the bottom of the connector (FIG. 5 item 560, or FIG. 11 item 1160), the outside shell of a USB-C connector (FIG. 15, item 1500C) is molded into shape, so it's very rigid and has no seam anywhere on it. Thus, the solution represented by embodiments of the current invention increase the gripping force between male and female connectors by adding the punched-out raised crowns on the USB A or USB B male connectors outside shell won't work with USB-C connectors. One embodiment of the current invention for such USB-C connectors adds a H like gripping member comprised of three members, left, right, and cross are shaped like a hand (FIG. 15, item 1500D to the connector). Here, the front left and front right members are like fingers with trapezoidal hooks that can grab the left and right dimples or notches to create much greater pull-out force when unplugging the male connector from the female connector. The detailed descriptions of this H like gripping fingers are in the next paragraph.

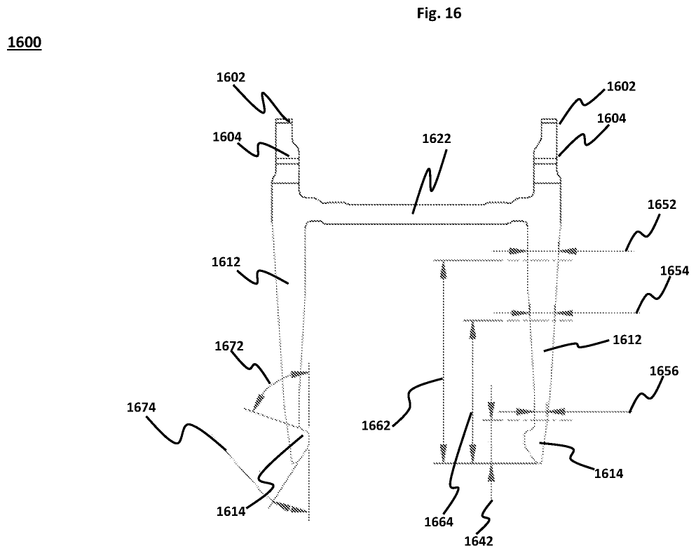

Referring to FIG. 16, a top angel 2D view of one embodiment of the current invention three member, left, right, and cross, H like gripping hand. It consists of a left and a right front member with trapezoidal hooks or gripping fingertips 1614 that are shaped like a hook, a left and a right front finger 1612, a left and a right rear fingers 1604, a left and a right rear fingertips 1602, and a link member arm 1622 that links the left fingers with the right fingers. The front fingertips 1614 trapezoidal hooks are designed to go over and sink into the matching dimples or notches inside the female connector to create a greater gripping force to prevent the male connector from un-mating from the female connector easily. In certain embodiments the three members, left, right, and cross, H-shaped gripping hand is about 0.2 to 0.4 mm in height or thickness to provide sufficient rigidity and strength for the frictional gripping of the hooks. Notably, the three members, left, right, and cross, H like gripping hand are not for providing for electrical grounding connection purposes, but are designed to be thicker for gripping functionality.

Embodiments of the current invention's front gripping fingertip's hook entry angle 1674 is between about 30 to about 36 degrees to provide an easy insertion for connector mating; the current preferred exit angle 1672 is at a much sharper angle of between about 60 to about 80 degrees to provide a much stronger gripping force to prevent connector from releasing or un-mating. Embodiments of the current invention's finger or trapezoidal hook's width 1656 near the front tip is quite wide between about 1.6 to about 1.9 mm; the current invention's finger width 1654 near the middle of the member finger is quite wide between about 3 to about 4 mm; the current invention's finger width 1652 near the rear of the finger is even wider between about 3.6 to about 5.0 mm to provide the strong gripping force needed to pull out the male connector from the female connector from about 30 N to about 40 N. The left and right rear member fingers 1604 and rear member fingertips 1602 are inserted into the slots inside the connector body (FIG. 15, item 1500B) to keep the three-member hand in place and to provide the counter force to keep the front member fingertips or trapezoidal hooks 1614 firmly pushed in when mated with a female connector. Although, in this embodiment of the current invention used a H like three-member hand with 2 front fingertips or trapezoidal hooks for gripping the notches inside the female connector; any other shaped hand, or hook, or any other shaped and number of fingers and hooks to grip the notches inside the female connector are contemplated as additional embodiments of this invention. Although, in the embodiment, the front finger's entry angle, exit angle, the finger widths at the front, middle and rear of the fingers are shown in the ranges in this paragraph as examples, any other angles or widths would be known by a skilled engineer and represent added embodiments of this invention since they use the same principle of using the member fingers and hooks in the male connector to grab the notches inside the female connector.

Prior Art Connector Plug Body Metal can with LED Holes

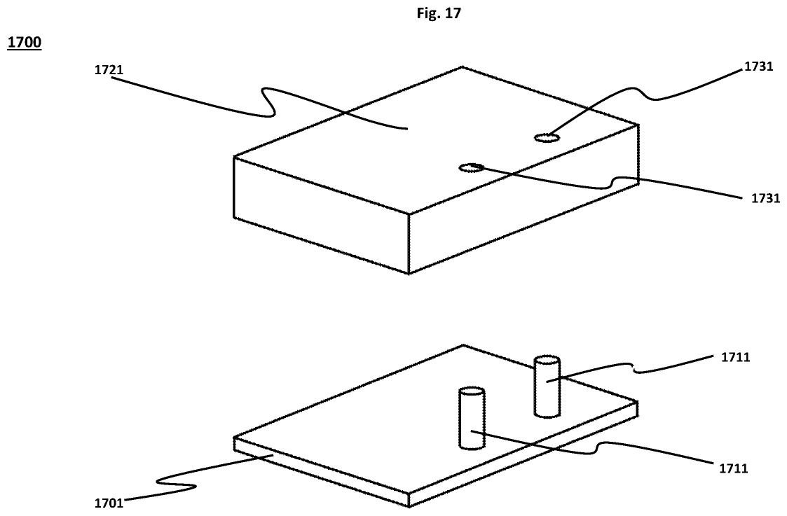

Referring to FIG. 17, view 1700, shown schematically is a prior art connector plug's internal Printed Circuit Board (PCB) and overall metal container or can. The internal PCB 1701 has one or several Light Emitting Diodes (LEDs) 1711. The overall metal container or can 1721 has one or more small holes 1731 that matches the location of the LEDs 1711 and allows the lights to come out for the user to see. The metal container or can 1721 has 5 surfaces connected to each other: top, front, rear, left and right. The metal container or can is clipped or soldered to the PCB 1701 with one of the PCB's copper layers serving as the bottom or the 6^{th} surface of the metal container (and optionally a lower piece of the metal container or can (not shown in FIG. 17)). This completes all 6 surfaces of the overall shielding. Because of the small holes 1731, now the metal can is not airtight; the internal circuit's high frequency emissions can escape from the holes 1731 and potentially interfere other devices nearby; or the outside high frequency emissions can leak into the internal circuit through the holes 1731 and can potentially interfere the inner circuit and the connected devices by this cable. The cables with these LED holes may not pass the industry EMI related compliance tests and so can be non-compliant with industry standards.

Embodiments of the Current Invention: Divided Inner Circuit with Thin Metal Walls to Achieve EMI Compliance

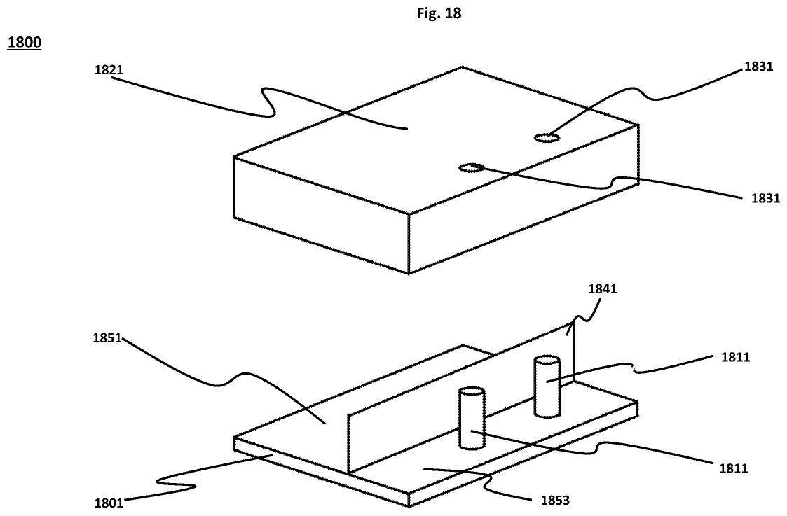

Now referring to FIG. 18, one embodiment of the current invention connector inner PCB and its EMI shielding design is shown. The inner PCB 1801, LEDs 1811, overall metal container or can 1821, small holes 1831 for LED light to come out are essentially identical to the items 1701, 1711, 1721, 1731 respectively in FIG. 17. There is no need to explain them again here. The partition 1841 is a novel preferred part of these embodiments of the invention. The partition can be a thin metal wall or walls of other composition that similarly divided the PCB 1701 into two or more sections. In this example illustrations, it's divided into two sections or chambers: a section 1851 with all the components and copper traces of the PCB for the high frequency signals; and a section 1853 with all the components and copper traces of the PCB for the low frequency signals, including the LED indication circuit, the power circuit, the control circuit or other circuits. When the overall metal container or can 1821 is clipped or soldered onto the PCB 1801, the top edge of the thin metal or other composition wall 1841 is pressed on and securely connected electrically with the inner surface of the overall metal container or can 1821's top surface. Thus, the four surfaces of the overall metal container or can, the top, front, rear and left surfaces, plus one surface of the thin metal or other composition wall 1841, and one surface of the ground plain of the PCB 1801 or the optional bottom metal can (not shown) will complete the nearly air tight six surfaces for the left chamber of the PCB around the PCB section 1851, and completes the nearly airtight EMI shielding for that section with high frequency signals. The other chamber around the PCB section 1853 formed by four surfaces of the overall metal can: top, front, rear and right surfaces, plus the one surface by the thin metal wall 1841, and one surface of the ground plain of the PCB 1801 or the optional bottom metal container or can (not shown) will complete the six surfaces, but are not air tight because of the holes 1831. However, the components and copper traces in this section only handles the low frequency signals like the LED indications, DC powers, control signals, which can't emit any significant EMI out; and also, are not sensitive to the EMI coming from outside devices and leaked in through the small holes 1831, thus there are likely no negative effects. Embodiments of this new invention provide a novel nonobvious design to solve the difficult problem of how to keep high frequency signal in near airtight EMI shielding yet still have open holes to allow LED lights to come out for indications and visualization.

What is claimed is:

1. A USB A or USB B gripping male connector comprising:
an outside shell with a male plug for contacting a female receptacle via the outside shell;
at least one raised crown on at least one surface of the connector's outside shell, wherein the raised crown protrudes-out from the metal and is raised above the at least one surface of outside shell;
the at least one raised crown further comprising at least one ramp separated from the surface of the connector's outside shell by at least one slot, and at least one dome of the raised crown; wherein the at least one slot and at least one ramp form a base of the dome of the raised crown, wherein the at least one slot and the at least one ramp, provides flexibility or give for the at least one raised crown to move downwards when the top of the raised crown or cone is compressed by the inner surface of the female receptacle's outside shell when the male plug is inserted into the female receptacle to create greater gripping force by friction.

2. The USB A or USB B male gripping connector of claim 1, wherein the raised crown further comprises four slots, four ramps, and one dome, wherein the ramps and slots form an X like configuration around the dome of the raised crown.

3. The USB A or USB B male gripping connector of claim 1, wherein the raised crown has two slots, two ramps, and one dome, wherein the ramps and slots form an H like configuration around the dome of the raised crown.

4. The USB A or USB B male gripping connector of claim 1, wherein the raised crown has three slots, three ramps, and one dome, wherein the ramps and slots form a Y like configuration around the dome of the of the raised crown.

5. The USB A or USB B male gripping connector of claim 1, wherein the raised crown further comprises a plurality of ramps and slots and wherein the ramps and slots forms a V, T, C, or K like configuration around the dome of the raised crown.

6. A USB-C male gripping connector comprising:
at least one member comprising at least one finger positioned in the inner portion of the male plug;
wherein the at least one front finger further comprises at least one tip wherein the tip is a trapezoid hook, wherein the junction between each side of the trapezoid hook is rounded; wherein the at least one tip is configured to slide through the inner surface of the mating female connector when inserted and drops into the at least one notch in the inner surface of the female connector to form the increase gripping force when the male connector is fully inserted.

7. The male USB-C gripping male connector of claim 6, wherein the member further comprises a left and a right member and a cross member perpendicular between the left and right member forming a H like configuration, wherein each of the left and right member comprises a tip.

8. The USB-C gripping male connector of claim 6, wherein the tip's hook is configured with an entry angle of about 30 to about 36 degrees; and wherein the tip's hook is configured with an exit angle of about 60 to about 80 degrees.

9. The male USB-C gripping male connector of claim 7, wherein
the width of a front portion of the left and right member's tip is from about 1.6 to about 1.9 mm;
wherein the width of the middle portion of the left and right member is from about 3 to about 4 mm;
wherein the width of the rear portion of the left and right member is from about 3.6 to about 5.0 mm, and
wherein the members are about 0.2 to about 0.4 mm in thickness.

10. The USB Male gripping connector of claim 1 or 6 wherein the gripping force is about 20 N to about 50 N.

11. The USB Male gripping connector of claim 7, wherein the members are not for electrical grounding connection purposes.

12. A connector plug body comprising:
a Printed Circuit Board (PCB) further comprising one or more Light-Emitting Diodes (LED), PCB traces and high frequency components and PCB traces in one section of the PCB, and all of the low frequency components including the LEDs and PCB traces in another section of the PCB,
an Electromagnetic Interference (EMI) shieling container, wherein the EMI shielding container can be chosen from the group consisting of a metal can, a copper tape wrap, and conductive ceramic; wherein the shielding container further comprises one or more openings matching the positions of the LEDs on the PCB to allow the LEDs to protrude so that light can be visualized from the LEDs,
at least one partition wall configured on the PCB connected to the ground circuit wherein the at least one partition divides the PCB with all the high frequency components and PCB traces in one section of the PCB, and all of the low frequency components including the LEDs and PCB traces in another section of the PCB;
and wherein the top of the at least one partition wall is in secure contact of the inner side of a top surface of the EMI shielding container to form near airtight EMI shielding for the inner chamber in the high frequency section of the PCB.

13. The connector plug body of claim 12, wherein the connector is chosen from the group consisting of USB, HDMI, DP, VGA, and other connector types.

14. The connector plug body of claim 12, wherein the partitions walls are made of material chosen from the group consisting of copper, tin, aluminum, steel, other conductive metals, and conductive ceramic.
